(19) United States
(12) Patent Application Publication
(10) Pub. No.: US 2011/0155225 A1
(43) Pub. Date: Jun. 30, 2011

(54) Back contact solar cells having exposed vias

(75) Inventors: James Howarth, Albuquerque, NM (US); Jeff Franklin, Albuquerque, NM (US); James M. Gee, Albuquerque, NM (US); Peter Hacke, Albuquerque, NM (US); David L. King, Albuquerque, NM (US)

(73) Assignee: Applied Materials, Inc., Santa Clara, CA (US)

(21) Appl. No.: 12/806,919

(22) Filed: Aug. 23, 2010

Related U.S. Application Data
(60) Provisional application No. 61/235,996, filed on Aug. 21, 2009.

(51) Int. Cl. H01L 31/02; H01L 31/0224

(52) U.S. Cl. 136/252; 438/98; 257/E31.124

(57) ABSTRACT

Embodiments of the invention contemplate the formation of a solar cell device that has improved efficiency and device electrical properties. In one embodiment, the solar cell device described herein includes an Emitter Wrap Through (EWT) solar cell that has plurality of laser drilled vias disposed in a spaced apart relationship to metal gridlines formed on a surface of the substrate. Solar cell structures that may benefit from the invention disclosed herein include back-contact solar cells, such as those in which both positive and negative contacts are formed only on the rear surface of the device.

### CROSS-REFERENCE TO RELATED APPLICATIONS

This application claims benefit of U.S. provisional patent application Ser. No. 61/235,996 (Atty. Docket. No.: APPM/014956L), filed Aug. 21, 2009, which is herein incorporated by reference.

### BACKGROUND OF THE INVENTION

1. Field of the Invention

The present invention relates to methods and processes for making the back-contact structure in a back-contact silicon solar cell and solar cells made by such methods.

2. Description of the Related Art

The solar cell design in widespread use today has a p/n junction formed near the front surface, or surface that receives the light, which generates electron/hole pairs as light energy is absorbed in the formed cell. The conventional cell design has one set of electrical contacts on the front side of the cell, and a second set of electrical contacts on the back side of the solar cell. In a typical photovoltaic module these individual solar cells are interconnected electrically in series to increase the voltage. This interconnection is typically accomplished by soldering a conductive ribbon from the front side of one solar cell to the back side of an adjacent solar cell.

Back-contact solar cells have both the negative-polarity and positive-polarity contacts on the rear surface. Back-contact silicon solar cells have several advantages compared to conventional silicon solar cells. The first advantage is that back-contact cells have a higher conversion efficiency due to reduced or eliminated contact obscuration losses (sunlight reflected from contact grid is unavailable to be converted into electricity). The second advantage is that assembly of back-contact cells into electrical circuits is easier, and therefore cheaper, because both conductivity type contacts are on the same surface. As an example, significant cost savings compared to present photovoltaic module assembly can be achieved with back-contact cells by encapsulating the photovoltaic module and the solar cell electrical circuit in a single step. The last advantage of a back-contact cell is better aesthetics through a more uniform appearance. Aesthetics is important for some applications, such as building-integrated photovoltaic systems and photovoltaic sunroofs for automobiles. FIG. 1 illustrates a typical back-contact cell structure. The silicon substrate may be n-type or p-type. One of the heavily doped emitters (n⁺⁺ or p⁺⁺) may be omitted in some designs. Alternatively, the heavily doped emitters could directly contact each other on the rear surface in other designs. Rear-surface passivation helps reduce loss of photogenerated carriers at the rear surface, and helps reduce electrical losses due to shunt currents at undoped surfaces between the contacts.

There are several approaches for making a back-contact silicon solar cell. These approaches include metallization wrap around (MWA), metallization wrap through (MWT), emitter wrap through (EWT), and back-junction structures. MWA and MWT have metal current collection grids on the front surface. These grids are, respectively, wrapped around the edge or through holes to the back surface in order to make a back-contact cell. The unique feature of EWT cells, in comparison to MWT and MWA cells, is that there is no metal coverage on the front side of the cell, which means that none of the light impinging on the cell is blocked, resulting in higher efficiencies. The EWT cell wraps the current-collection junction (“emitter”) from the front surface to the rear surface through doped conductive channels in the silicon substrate. “Emitter” refers to a heavily doped region in a semiconductor device. Such conductive channels can be produced by, for example, drilling holes in the silicon substrate with a laser and subsequently forming the emitter inside the holes at the same time as forming the emitter on front and rear surfaces.

Back-junction cells have both the negative and positive polarity collection junctions on the rear surface of the solar cell. Because most of the light is absorbed, and therefore also most of the carriers are photogenerated, near the front surface, back-junction cells require very high material quality so that carriers have sufficient time to diffuse from the front to the rear surface with the collection junctions on the rear surface. In comparison, the EWT cell maintains a current collection junction on the front surface, which is advantageous for high current collection efficiency. The EWT cell is disclosed in U.S. Pat. No. 5,468,652, Method Of Making A Back Contacted Solar Cell, to James M. Gee, incorporated herein by reference. The various other back contact cell designs have also been discussed in numerous technical publications. In addition to U.S. Pat. No. 5,468,652, two other U.S. patents on which Gee is a co-inventor disclose methods of module assembly and lamination using back-contact solar cells, U.S. Pat. No. 5,951,786, Laminated Photovoltaic Modules Using Back-Contact Solar Cells, and U.S. Pat. No. 5,972,732, Method of Monolithic Module Assembly. Both patents disclose methods and aspects that may be employed with the invention disclosed herein, and are incorporated by reference as if set forth in full. U.S. Pat. No. 6,384,316, Solar Cell and Process of Manufacturing the Same, discloses an alternative back-contact cell design, but employing MWT, wherein the holes or vias are spaced comparatively far apart, with metal contacts on the front surface to help conduct current to the rear surface, and further in which the holes are lined with metal.

A critical issue for any back-contact silicon solar cell is developing a low-cost process sequence that also electrically isolates the negative and positive polarity grids and junctions and has good electrical characteristics. The technical issue includes patterning of the doped layers, passivation of the surface between the negative and positive contact regions, and application of the negative and positive polarity contacts. Note that the discussion herein refers to a number of publications by author(s) and year of publication, and that due to recent publication dates certain publications are not to be considered as prior art. Discussion of such publications herein is given for more complete background and is not to be construed as an admission that such publications are prior art for patentability determination purposes.

Typical Emitter Wrap Through (EWT) solar cells, which are one type of back contact solar cell, incorporate the use of laser drilling or other formation of vias through a silicon substrate to allow for a connection of the front emitter to the rear emitter of the solar cell. This laser drill step is typically performed at the beginning of the solar cell formation process. Typically, prior art EWT designs utilize negative-polarity metal (“n-metal”) gridlines that are placed/printed directly over the laser drilled vias, as shown in FIG. 4. The metal deposited over the via architecture was thought to be necessary to minimize the series resistance of the formed solar cell by including high conductivity metal inside the formed via holes. However, it was found that this architecture has many disadvantages, especially when using screen printed metallizations, because the placement of the metal in the via hole results in poor device electrical characteristics. Therefore, there is a need for an improved solar cell device architecture. As discussed below, surprisingly it was found that embodiments of the invention disclosed herein can achieve equally low or lower series resistance values using an improved solar cell architecture, while also doing away with the processing and device issues associated with metal inside the vias.

### SUMMARY OF THE INVENTION

The present invention generally provides a solar cell device, comprising a substrate having a first array of vias formed between a front surface and a rear surface of the substrate, a first gridline disposed on the rear surface, and a second gridline disposed on the rear surface, wherein the first array of vias are disposed between the first gridline and the second gridline.

Embodiments of the present invention may also provide a solar cell device, comprising a substrate having a first array of vias and a second array of vias that are both formed between a front surface and a rear surface of the substrate, wherein the substrate is doped with a first doping element, a doped region formed on at least a portion of the front surface, a surface of the vias in the first array of vias, a surface of the vias in the second array of vias, and at least a portion of the rear surface, wherein the doped region is doped with a second doping element that is of an opposite doping type to the first doping element, a first gridline disposed on the rear surface and a distance along the rear surface from the first array of vias, and a second gridline disposed on the doped region formed on the rear surface, and between the first array of vias and the second array of vias.

Embodiments of the present invention may also provide a method of forming a solar cell device, comprising forming a first array of vias in a substrate that is doped with a first doping element, wherein the first array of vias are formed between a front surface and a rear surface of the substrate, forming a doped region on at least a portion of the front surface, on a surface of the vias in the first array of vias and at least a portion of the rear surface, wherein the doped region is doped with a second doping element that is of an opposite doping type to the first doping element, depositing a first gridline on the rear surface and a distance along the rear surface from the first array of vias, and depositing a second gridline between the first array of vias and the second array of vias on the doped region formed on the at least a portion of the rear surface.

Objects, advantages and novel features, and further scope of applicability of the present invention will be set forth in part in the detailed description to follow, taken in conjunction with the accompanying drawings, and in part will become apparent to those skilled in the art upon examination of the following, or may be learned by practice of the invention. The objects and advantages of the invention may be realized and attained by means of the instrumentalities and combinations particularly pointed out in the appended claims

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

The patent or application file contains at least one drawing executed in color. Copies of this patent or patent application publication with color drawing(s) will be provided by the Office upon request and payment of the necessary fee.

FIG. 1 is an illustration of a generic back-contact solar cell, highlighting only features on the back surface.

FIGS. 2A-2E are schematic cross-sectional views that illustrate the various processing steps used to form a solar cell according to one embodiment of the invention.

FIG. 3 illustrates processing steps used to form the solar cell illustrated in FIGS. 2A-2E according to an embodiment of the invention.

FIG. 4A Illustrates a plurality of interdigitated gridlines disposed over a rear surface of a prior art EWT solar cell.

FIG. 4B Illustrates a rear surface of a prior art EWT solar cell comprising a gridline disposed over laser drilled vias architecture.

FIG. 5 shows the rear surface of a solar cell comprising vias offset to single side of a gridline architecture according to an embodiment of the invention.

FIG. 6 shows the rear surface of a solar cell comprising vias alternating on each side of a gridline architecture in a “parallel” configuration according to an embodiment of the invention.

FIG. 7 shows the rear surface of a solar cell comprising vias alternating on each side of a gridline architecture in a staggered configuration according to an embodiment of the invention.

FIG. 8 is a chart illustrating measured pseudo fill factor data for solar cells comprising different via configurations according to an embodiment of the invention.

FIG. 9 is a chart illustrating measured non-ideal saturation current J₀₂ data for solar cells comprising different via configurations according to an embodiment of the invention.

FIG. 10 is a chart illustrating measured fill factor data for solar cells comprising different via configurations according to an embodiment of the invention.

FIG. 11 is a chart illustrating measured efficiency data for solar cells comprising different via configurations according to an embodiment of the invention.

FIG. 12 is a chart illustrating measured shunt resistance (R_{sc}) data for solar cells comprising different via configurations according to an embodiment of the invention.

FIG. 13A is a chart illustrating the measured series resistance (Rₛₑᵣᵢₑₛ) data for solar cells having a via configuration similar to the vias illustrated in FIG. 4B (“BL”) and a via configuration similar to the vias illustrated in FIG. 6 (“AS”) according to an embodiment of the invention.

FIG. 13B is a chart illustrating the measured series resistance (Rₛₑᵣᵢₑₛ) data for solar cells having different via configurations according to an embodiment of the invention.

FIG. 14 is a close-up view of a front surface of a solar cell in which the gridline material printed over a FIG. 4 type via configuration has migrated through the via to the front surface of the solar cell.

FIG. 15 is a close-up view of an array of vias formed on a solar cell similar to the architecture illustrated in FIG. 7 according to an embodiment of the invention.

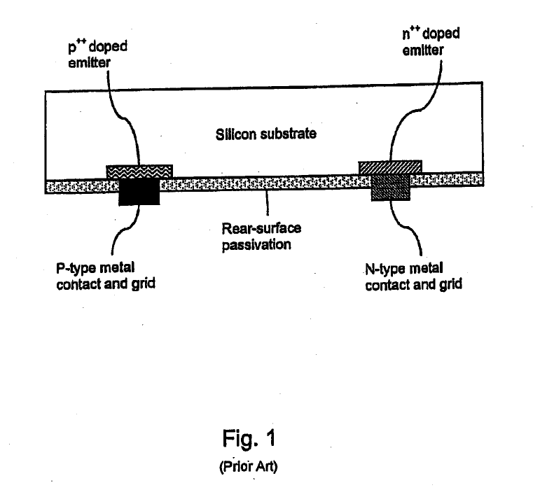

For clarity, identical reference numerals have been used, where applicable, to designate identical elements that are common between figures. It is contemplated that features of one embodiment may be incorporated in other embodiments without further recitation.

### DETAILED DESCRIPTION OF THE INVENTION

Embodiments of the invention contemplate the formation of a solar cell device that has improved efficiency and device electrical properties. In one embodiment, the solar cell device described herein includes an Emitter Wrap Through (EWT) solar cell that has plurality of laser drilled vias disposed in a spaced apart relationship to metal gridlines formed on a surface of the substrate. As used throughout the specification and claims, the term “gridline” means a thin metal conductor that transports current to the bus bars and bus pads that typically comprise an interconnect of a back contact solar cell. Solar cell structures that may benefit from the invention disclosed herein include back-contact solar cells, such as those in which both positive and negative contacts are formed only on the rear surface of the device. Solar cell devices that may benefit from the ideas disclosed herein may include devices containing materials, such as single crystal silicon, multi-crystalline silicon, polycrystalline silicon, germanium (Ge), gallium arsenide (GaAs), cadmium telluride (CdTe), cadmium sulfide (CdS), copper indium gallium selenide (CIGS), copper indium selenide (CuInSe₂), gallium indium phosphide (GaInP₂), as well as heterojunction cells, such as GaInP/GaAs/Ge, ZnSe/GaAs/Ge or other similar substrate materials that can be used to convert sunlight to electrical power.

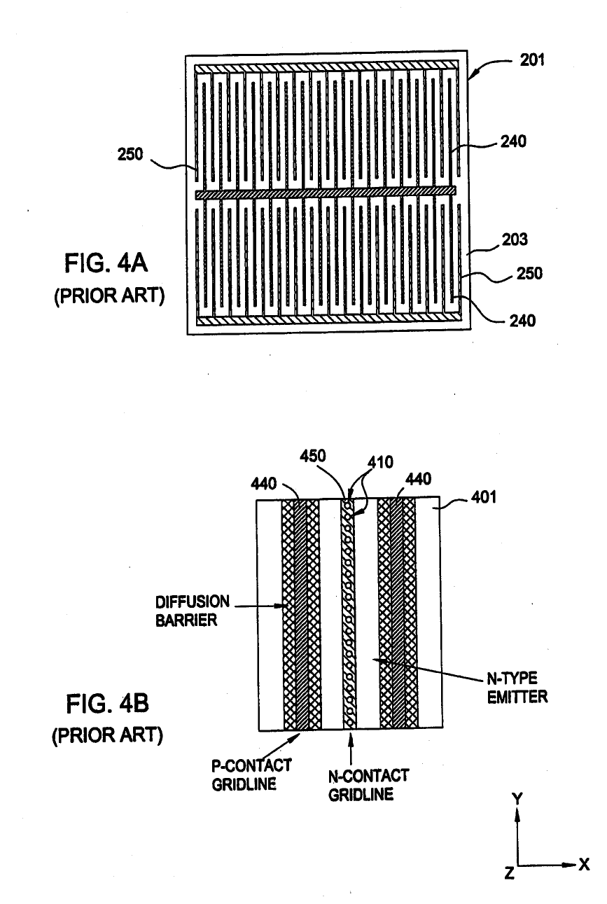

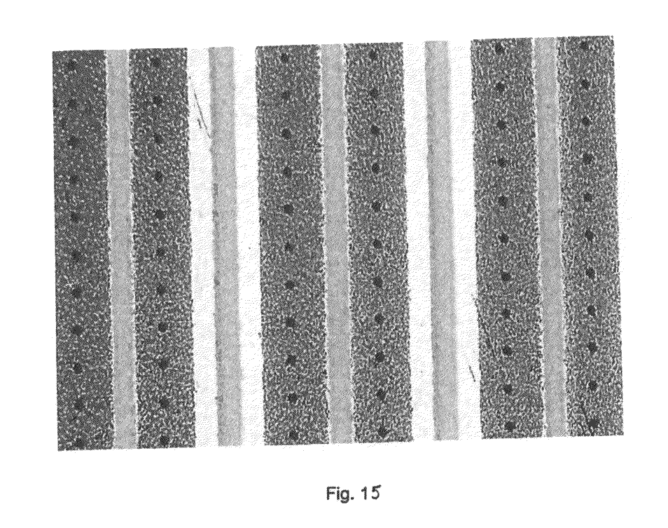

FIG. 4A is a plan view of the rear surface 403 of a prior art solar cell design having an interdigitated array of first gridlines 440 that are spaced a distance from second gridlines 450. FIG. 4B is a close-up plan view of a portion of the rear surface 403 of a prior art solar cell design having an interdigitated array of first gridlines 440 and second gridlines 450, wherein the second gridlines 450 are disposed over a series of vias 410. The vias 410 are generally holes that extend from the front surface to the rear surface of the solar cell substrate 401. It has been found that configurations that utilize metallization schemes that require placing a metal gridline over vias has many disadvantages. One disadvantage is that the deposited metal material used to form the second gridline will tend to migrate or be pushed through the via 410 and be deposited on the front surface 402 of the solar cell during the metal deposition process. If the gridline is deposited using a screen printing process, then any deposited metal material that migrates to the front surface 402 will also contaminate the screen printing hardware, such as the printing nest, which will require the screen printing tool to be taken out of operation to be cleaned. Also, metal materials deposited on the front surface 402 will affect the surface area through which light can be absorbed by the solar cell and will also generally create a cosmetic defect that will cause the solar cell to be scrapped. FIG. 15 illustrates a solar cell, similar to the device shown in FIG. 4B, that has a metallic material that has “bled” through to the front surface of a solar cell device. A second disadvantage of placing a gridline over formed vias 410 is that the surface roughness, doping level and surface cleanliness will affect the quality of the electrical contact formed between the deposited gridline metal and the surface of the solar cell in the via 410. In this configuration, non-ideal recombination losses, which are often created by poor electrical contact created between the gridline metal and the imperfect surface of the vias 410, becomes a significant factor that will affect the overall efficiency of the formed solar cell device. A third disadvantage of placing a gridline over formed vias 410 is that the amount of gridline metal in each via 410 will vary due to the placement of the gridline and common variation in the conventional gridline deposition techniques, which can cause the solar cell device properties to vary from one solar cell device to the next. A fourth disadvantage of placing a gridline over formed vias 410 is that the metal deposited over the vias tends to migrate into the vias creating interruptions in the gridline on the rear surface 203 that affect the actual cross-sectional area of the gridline through which the collected electrical current can pass, thus increasing the resistance of the gridline and reducing the efficiency of the solar cell device.

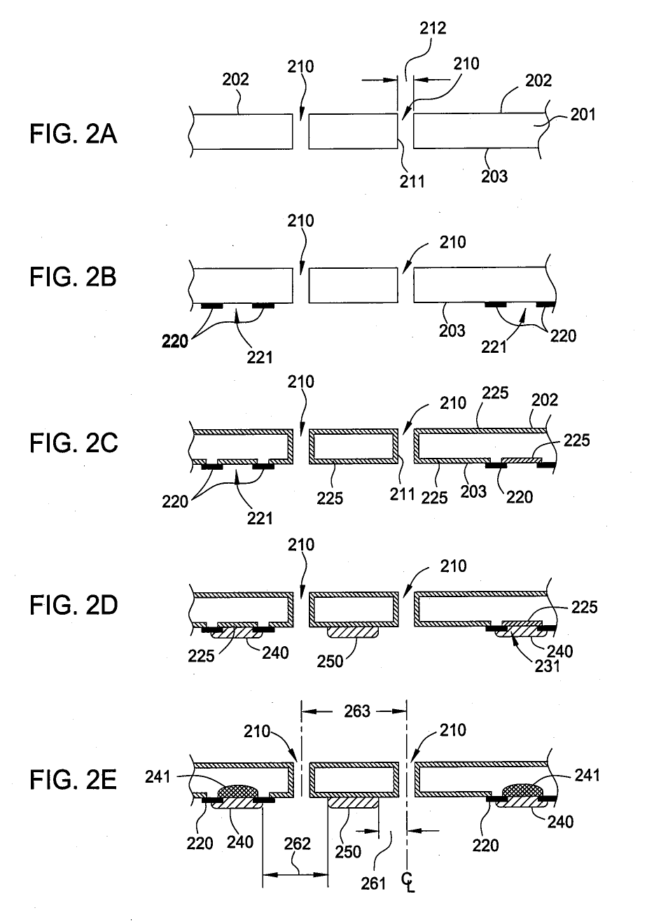

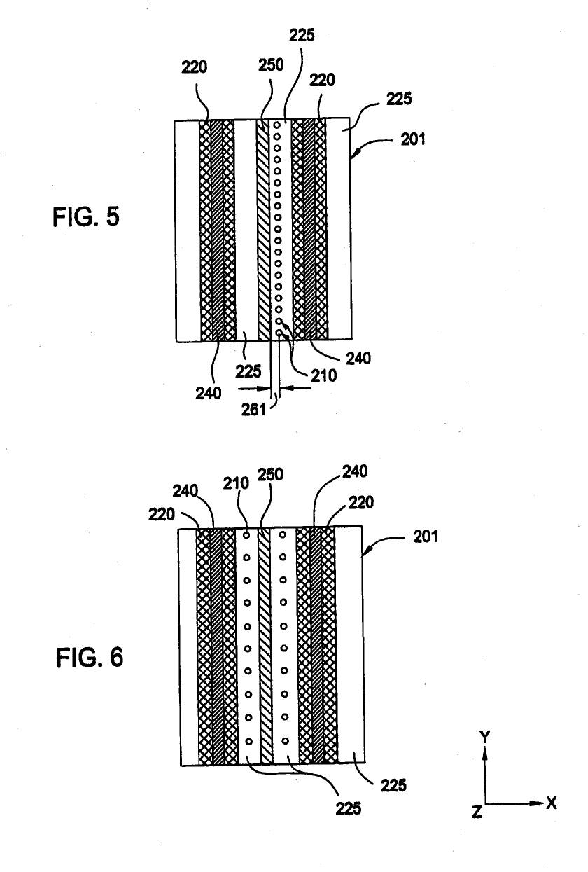

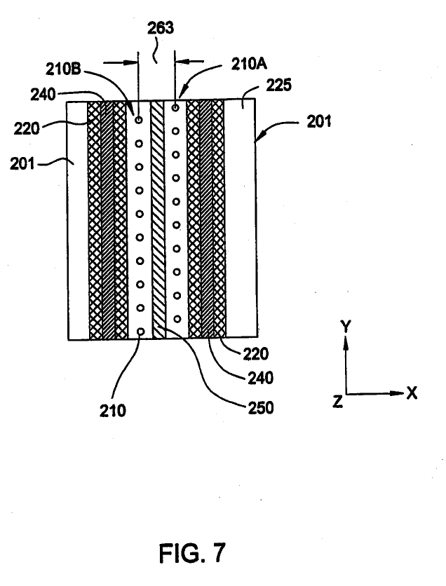

FIGS. 5-7 illustrate various embodiments of a rear surface 203 of a novel formed solar cell device having an interdigitated array of first gridlines 240 and second gridlines 250 that have plurality of vias 210 disposed between the gridlines. As noted above, embodiments of the present invention generally include a configuration where no metallization is disposed over the vias 210 formed in the substrate 201. FIG. 2E is a side cross-sectional view of a formed solar cell device that is configured similar to the designs illustrated in FIGS. 6 and 7. In these embodiments, the vias 210 are preferably positioned to the side of the second gridline 250 (e.g., negative-polarity “n-metal” gridline) in the emitter area between the second gridline 250 and diffusion barrier structure (e.g., reference numeral 220) formed with the first gridline 240 (e.g., positive-polarity “p-metal” gridline). In one embodiment, the vias 210 are positioned halfway between the first gridline 240 and the second gridline 250 (e.g., n-metal gridline). FIG. 5 is a plan view of the rear surface 203 of a solar cell device that illustrates one embodiment of a solar cell device that has a single array of offset vias 210 that are formed to one side of a second gridline 250. In one example, the single array of vias 210 are offset a distance 261 (FIGS. 2E and 5) from the second gridline 250. FIG. 6 is a plan view of the rear surface 203 of a solar cell device that illustrates one embodiment of a solar cell device that has an array of vias 210 that are formed between a second gridline 250 and each adjacently positioned first gridline 240. FIG. 7 illustrates one embodiment of a solar cell device that has an array of vias 210 that are formed in a staggered orientation between a second gridline 250 and each adjacently positioned first gridline 240, which are formed on the rear surface 203.

The configurations shown in FIGS. 6 and 7 also have a number of advantages over the other configurations, such as shown in FIG. 4, due to the ease of manufacturing, including but not limited to the ability to accommodate a wider tolerance of via 210 placement accuracy during the laser drill step, and a wider tolerance of first and second gridline 240, 250 placement during their deposition steps. This advantage arises because via 210 must be accurately aligned with the metal gridline 250 in the prior art design illustrated in FIG. 4B. Another advantage of offsetting the vias from the gridline is the elimination of metal deposition through the hole and to the opposite surface. Although the via configuration shown in FIG. 5 also eliminates metal paste bleed through, as discussed above this configuration generally has a higher series resistance for equal via densities (# vias/mm²) when compared with the architectures shown in FIGS. 6 and 7, since the vias in the FIGS. 6 and 7 configurations are more uniformly distributed across the surface of the solar cell, as illustrated in the close-up view of a formed solar cell device shown in FIG. 15.

The embodiments illustrated in FIGS. 5-7 have numerous advantages over the configuration illustrated in FIG. 4B, which generally include the reduction in the required placement accuracy of vias relative to the gridlines, and the diameter of the formed vias 210 is not limited to the width of the gridlines. In the configurations, illustrated in FIGS. 6-7 the series resistance formed between the emitter regions formed on the front surface is greatly reduced by the increased density of the current paths created by the vias.

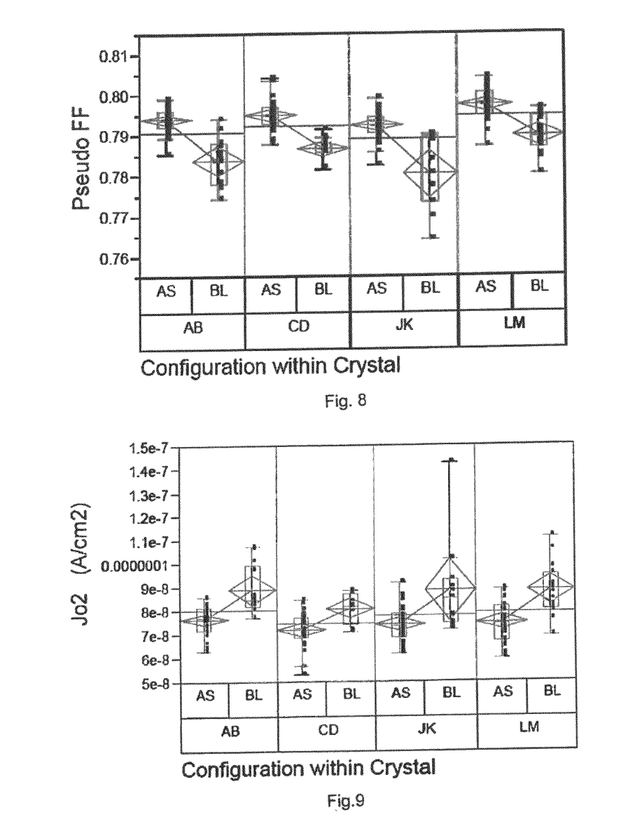

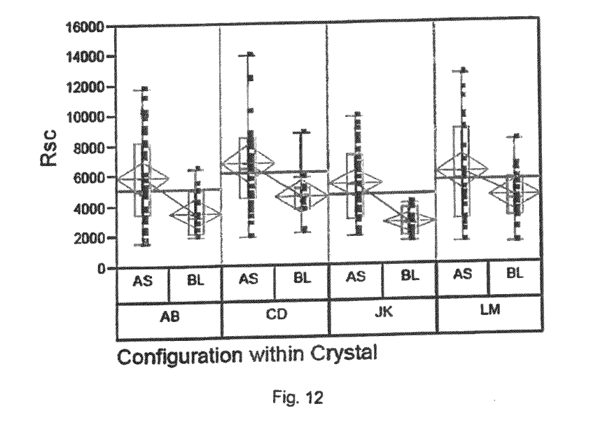

FIGS. 8-12 illustrate various process results which compare the solar cell device configuration shown in FIG. 7 (abbreviated as “AS”) versus the configuration shown in FIG. 4B (abbreviated as “BL”). FIG. 8 illustrates a measured pseudo fill factor for different via configurations and for various types of multi-crystalline substrates (e.g., AB, CD, JK, and LM). Pseudo fill factor measures the quality of the solar cell electrical properties with a higher value indicating higher quality. One skilled in the art will appreciate the statistically significant increase in the measured pseudo fill factor values between the FIG. 7 type solar cell configuration and the prior art type FIG. 4B configuration, for all types of substrates. FIG. 9 illustrates a measured fitted parameter, namely saturation current J₀₂ associated with non-ideal recombination, process results for various multi-crystalline substrates (e.g., AB, CD, JK, and LM). J₀₂ provides a measurement of the non-ideal diode properties of the solar cell, and a smaller value indicates a higher quality. One skilled in the art will appreciate the statistically significant decrease in the measured saturation current J₀₂ values between the FIG. 7 type configuration and the prior art type FIG. 4B configuration, for all types of substrates. It is believed that the decrease in the saturation current J₀₂ created by use of the embodiments described herein, which include the positioning of the array of vias 210 a distance from the gridlines, is related to the reduction in recombination losses associated with the metal inside the via.

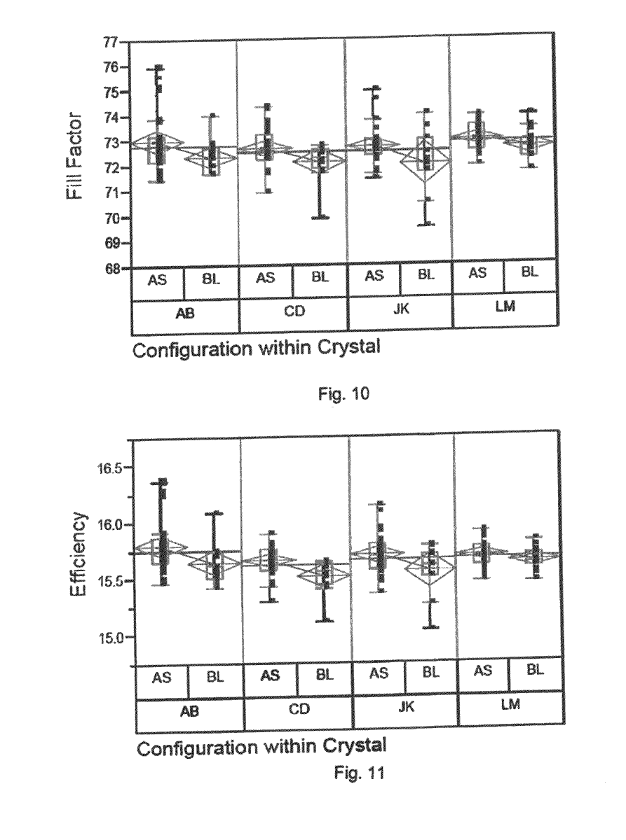

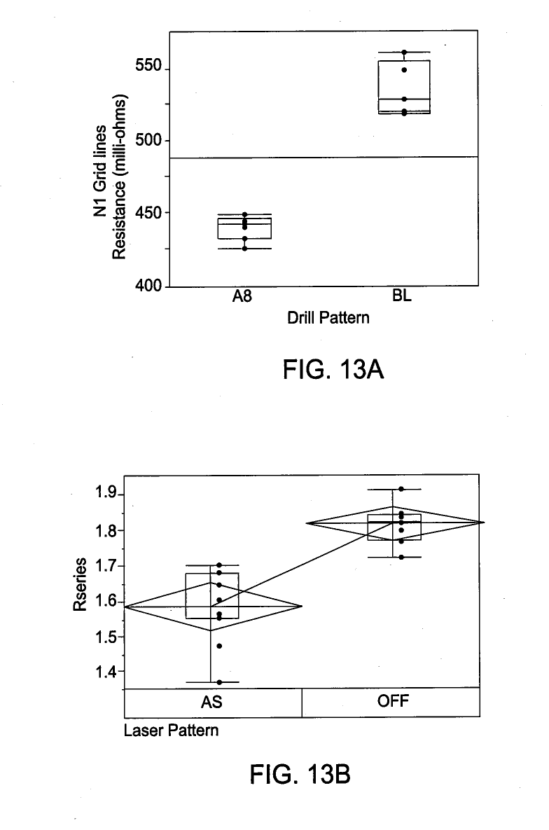

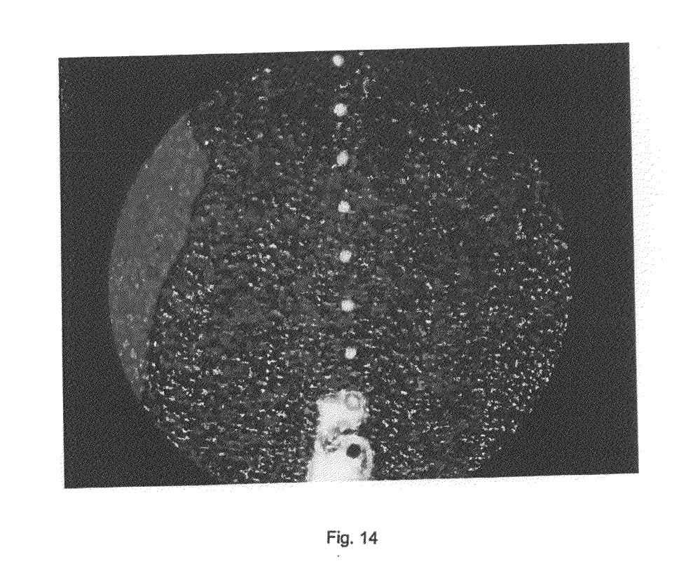

FIGS. 10-12 illustrate a measured photovoltaic I-V measurement process results, such as shunt resistance (R_{SC}), fill factor (FF) and conversion efficiency, for various multi-crystalline substrates (e.g., AB, CD, JK, and LM). One skilled in the art will appreciate the statistically significant increase in the measured R_{sc}, FF and efficiency values between the FIG. 7 type configuration and the prior art type FIG. 4B configuration, for all types of substrates. As illustrated in FIG. 13A, the FIG. 7 type configuration exhibits a lower series resistance versus the prior art type FIG. 4B configuration, due to a reduction of the emitter series resistance component contribution to the overall series resistance of the EWT cell. Typically the emitter series resistance component is proportional to the square of the via column spacing.

Further, as shown in FIG. 13B, the FIG. 7 type configuration exhibits a lower series resistance versus the configuration illustrated in FIG. 5, due to the higher via density in the substrate and thus a reduction of the series resistance in the EWT cell. Because the via column to column spacing, for example spacing 263 in FIG. 2E, is minimized for the AS configuration versus the offset configuration shown in FIG. 5 (abbreviated as “OFF”), the front emitter resistance is minimized, and the AS configuration has lower series resistance compared with the OFF configuration.

### Solar Cell Formation Process

Embodiment of the invention disclosed herein provide improved methods and processes for fabrication of an improved back-contact solar cell device, particularly methods and processes providing for the formation of a more efficient solar cell device due to a reduction in the series resistance created between an emitter region formed on the front surface of the solar cell device and the gridlines, and an improved saturation current (J₀₂). It is to be understood that while a number of different discrete methods are disclosed, one of skill in the art could combine or vary these method steps, thereby providing an alternative additional method of fabrication. It should also be understood that while the figures and example process sequences describe fabrication of back-contact emitter-wrap-through cells, these process sequences can be used for fabrication of other back-contact cell structures such as MWT, MWA, or back-junction solar cells.

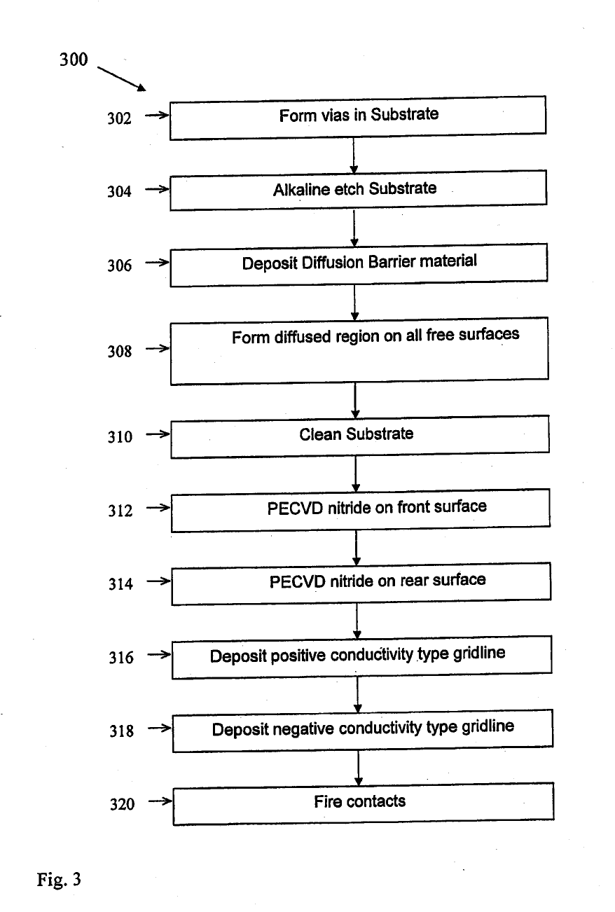

FIGS. 2A-2E are schematic cross-sectional views illustrating different stages of a processing sequence that are used to form a solar cell device 100. FIG. 3 illustrates an exemplary process sequence 300 used to form a solar cell device 100. The sequence found in FIG. 3 corresponds to the stages depicted in FIGS. 2A-2E, which are discussed herein. The methods of forming the solar cell device 100 described herein are not intended to be limiting and are only intended to represent one method of forming such a solar cell device.

At step 302, and as shown in FIG. 2A, a plurality of vias 210, or holes, are formed through the solar cell substrate 210. The vias 210 formed through the substrate 201 connect the front surface 202 to the rear surface 203 through a via surface 211, and are preferably formed by a laser drilling process. The vias 210 may also be formed by other processes, such as dry etching, wet etching, mechanical drilling, or water jet machining. Laser drilled vias 210 are preferably formed using a laser that is able to deliver sufficient power and/or electromagnetic radiation intensity at the operating wavelength to form the vias 210 in the shortest time, such as between about 1,000 and 20,000 holes per second. Shortening the via formation time will generally increase the substrate processing throughput and reduce the amount of heat and stress induced in the substrate during the via formation process. One laser that may be employed is a Q-switched Nd:YAG laser. The time required to form vias 210 in progressively thinner substrates will generally be proportionally reduced. The diameter 212 of the formed via 210 may be from about 25 to 125 μm diameter, preferably from about 30 to 80 μm diameter. In one embodiment, when employing thin solar cell substrates, such as substrates with a thickness of 100 μm or less, the via diameter 212 is approximately greater than or equal to the substrate thickness. The via 210 density per unit surface area of the front surface 202, or rear surface 203, is dependent on the acceptable total series resistance loss due to current transport in the emitter region formed on the front surface 202 through the vias 210 to the rear surface 203 and second gridline 250. In general, the density of vias 210 can be decreased as the sheet resistance of the emitter region 225 is reduced, such as determined by Ohms per square (Ω/sq). In one embodiment, the density of vias 210 (FIG. 2A) formed through the substrate 201 is between about 0.5 holes/mm² and about 10 holes/mm², but may be a lower density, such as one hole per 0.25-0.5 holes/mm². In one embodiment, the density of vias formed through the substrate 201 is between about 1-5 holes/mm². One skilled in the art will appreciate that as the diameter of the vias 210 increases the cross-sectional area through which the generated current can pass, and thereby reduce the resistance. However, increasing the size and/or density of vias 210 will affect the amount of energy required to form each of the vias, the throughput of the via formation process, and the usable surface area of the front side of the solar cell device.

In one embodiment, during step 302, two or more arrays of vias are formed through the substrate 210 in a spaced apart relationship. In one example, as illustrated in FIGS. 5-7, each of the arrays of vias are formed in a linear array of holes that can be aligned parallel to each adjacent array of vias and/or the first and second gridlines. While one or more linear arrays of vias are shown in FIGS. 5-7 this configuration of vias is not intended to be limiting as to the scope of the invention described herein, since other via array shapes or via configurations can be used. Referring to FIG. 7, in one embodiment, a first array of vias 210A are spaced a distance 263 in the x-direction from the second array of vias 210B, and are staggered relative to the second array 201B in the y-direction. Staggering of the arrays of vias can help reduce the distance a generated carrier needs to flow as it moves from the front surface to the rear surface of the solar cell device.

As noted above, the step of laser drilling holes may optionally be replaced by another method of forming vias, including but not limited to a gradient driven process such as thermomigration. Such processes are more fully disclosed in commonly owned International Application No. PCT/US2004/020370, filed Jun. 24, 2004, entitled “Back-Contacted Solar Cells with Integral Conductive Vias and Method of Making”, which is herein incorporated by reference.

Next, at step 304, the surfaces of the substrate 201, such as the front surface 202, rear surface and via surface 211 are etched to remove any undesirable material or crystallographic defects from the wafer production process and the laser machining process. In one embodiment, the etch process may be performed using a batch etch process in which the substrates are exposed to an alkaline etching solution. The substrates can be etched using a wet cleaning process in which they are sprayed, flooded, or immersed in a etchant solution. The etchant solution may be a conventional alkaline cleaning chemistry, such as a potassium hydroxide, or other suitable and cost effective etching solution. This step might additionally texture the surface for improved light collection.

Next, at step 306, and as shown in FIG. 2B, a diffusion barrier material 220 is disposed over the rear surface 203 of the substrate 201. In one embodiment, the diffusion barrier material 220 comprises an oxide and/or nitride material. In one example, the diffusion barrier material 220 comprises a silicon oxide, a silicon nitride or a metal oxide material that is disposed over a p-type silicon substrate. Optionally, the diffusion barrier material 220 may also comprise a p-type dopant (e.g., borosilicate glass “BSG” material) in order to provide a back surface field beneath the diffusion barrier. In one embodiment, as illustrated in FIG. 2B the diffusion barrier material 220 may be formed on the rear surface 203 so that isolated regions 221 of the substrate 201 are left exposed. In one configuration, the deposited diffusion barrier material 220 is deposited in a pattern to form isolated regions 221 that comprise a series of holes or long channel like regions of exposed substrate surface, which are surrounded, and thus are isolated from other regions of the rear surface 203. A patterned diffusion barrier material 220 layer may be formed by use of a screen printing, stenciling, ink jet printing, rubber stamping or other useful application method that provides for accurate placement of the diffusion barrier material 220 on these desired locations of the substrate. In some embodiments, the diffusion barrier material 220 is formed over the rear surface 203 by a CVD deposition and then patterned with a patterning process, such as screen-printed resist followed by chemical etch.

Next, at step 308, and as shown in FIG. 2C, a diffused region 225 is formed over the front surface 202, via surface 211, and the exposed regions of the rear surface 203 of the substrate 201. In one embodiment, the diffused region 225 comprises an n⁺ diffusion region (e.g., phosphorous doped) formed in a p-type solar substrate (e.g., boron doped silicon substrate). The diffused region 225 formation process may be performed by use of a conventional furnace doping process that can drive-in one or more dopant atoms. In one example, a POCl₃ diffusion step is performed to produce a diffused region 225 that is an n⁺ doped region. In general, it is desirable to create a doping profile in the front surface 202 that is different than the doping profile in the via surface 211 and back surface 203, so that the amount of light collected at the front surface 202 is maximized and the series resistance formed between the front surface 202 and the gridline 250 formed on the rear surface 203 is reduced. In one embodiment, it is desirable to create a doping profile in the portion of the diffused region 225 formed on the front surface 202 that has a sheet resistance of between about 60Ω/sq and about 200Ω/sq, and a doping profile in the portion of the diffused region 225 formed on the via surface 211 and the rear surface 203 that has a sheet resistance of between about 20Ω/sq and about 80Ω/sq, such as about 40Ω/sq. In another embodiment, to simplify the solar cell device formation process a single dopant concentration profile is created in the diffused region 225, which is formed across the front surface 202, via surface 211 and portions of the back surface 203. In this configuration, for example, the dopant concentration in the diffused region 225 is doped to achieve a sheet resistance between about 60Ω/sq and about 80Ω/sq. In one embodiment, the dopant concentration in the diffused region 225 is doped to achieve a sheet resistance of greater than about 60Ω/sq, since doping levels on the front surface of the solar cell that are less than about 60Ω/sq will tend to inhibit light absorption, and thus decrease solar cell efficiency.

Next, at step 310, the substrate 201 is cleaned to remove any undesirable formed oxide materials and/or surface contamination found on the surface of the substrate after step 308 has been performed. In one embodiment, the clean process may be performed using a batch cleaning process in which the substrates are exposed to a hydrofluoric acid (HF) containing cleaning solution. The substrates can be cleaned using a wet cleaning process in which they are sprayed, flooded, or immersed in a cleaning solution.

Next, at steps 312 and 314, in one embodiment, a thin passivation and/or antireflection layer (not shown) are formed over the front surface 202, via surface 211 and/or portions back surface 203. The thin passivation and/or antireflection (ARC) layer may be a dielectric layer, preferably comprising a nitride (e.g., silicon nitride), that is preferably disposed on front cell surface 202 in order to passivate the surface and provide an anti-reflection coating. In one embodiment, a passivation and ARC layer is formed on the front surface 202 and portions of the vias 210 in step 312, and then a passivation and ARC layer is formed on the rear surface 203 and portions of the vias 210 in step 314. In one embodiment, the thin passivation and/or antireflection layer is formed using a conventional PECVD, thermal CVD or other similar formation process.

At box 316, as illustrated in FIG. 2D, a first gridline 240 is deposited over the isolated regions 221 formed between portions of the diffusion barrier material 220 using a conventional deposition process, such as a screen printing process. In one embodiment, the first grid line 240 material is selected so that during the subsequent contact firing process a p-type region 241 (FIG. 2E) is formed in the substrate by the reaction of the deposited metal material and the substrate 201 material (e.g., p-type silicon substrate). In one embodiment, the first grid line 240 material comprises an aluminum material that is able to form a p-type region 241 in the substrate 201 during the firing process. The aluminum or aluminum alloy preferably reacts with silicon above the eutectic temperature. However, in some embodiments, the first grid line 240 may contain a metal, such as aluminum (Al), copper (Cu), silver (Ag), gold (Au), tin (Sn), cobalt (Co) nickel (Ni), zinc (Zn), lead (Pb), molybdenum (Mo), titanium (Ti), tantalum (Ta), vanadium (V), tungsten (W), or chromium (Cr).

At box 318, as illustrated in FIG. 2D, a second gridline 250 is deposited over a region of the rear surface 203 using a conventional deposition process, such as a screen printing process. In one embodiment, the second grid line 250 is disposed over the n+ region formed on a substrate 201 (e.g., p-type silicon substrate), and comprises a silver containing material. Most silver (Ag) pastes deposited by a screen printing process may contain materials, such as an oxide frit, that facilitate alloying through any surface oxides, or through an antireflection coating (e.g., step 314; generally around 70 nm thick). However, in some embodiments, the second grid line 250 may contain a metal, such as aluminum (Al), copper (Cu), silver (Ag), gold (Au), tin (Sn), cobalt (Co) nickel (Ni), zinc (Zn), lead (Pb), molybdenum (Mo), titanium (Ti), tantalum (Ta), vanadium (V), tungsten (W), or chromium (Cr).

In one embodiment, the spacing 262 between the first gridline 240 and the second gridline 250 is between about 0.5 mm and 1.5 mm for gridlines that are about between 15 μm and 300 μm wide. One skilled in the art will appreciate that the configuration of vias and gridlines has many advantage over prior art configurations, such as the configurations illustrated in FIG. 4B, since it allows the gridline widths to be reduced (e.g., reducing material cost), and the required accuracy of the placement of the gridlines on the rear surface 203 to also be reduced.

At box 320, a conventional contact firing process is performed to assure that the first and second gridlines 240, 250 make a good electrical contact to the desired regions of the substrate 201. In this step, the substrate is heated to desirable temperature to form a good electrical contact between the first gridline 240 and the substrate 201, and the second gridline 250 and the substrate 201. As noted above, in one embodiment, the substrate is heated to a desirable temperature so that a metal in the first gridline is able to react with the material at the surface of the substrate to form a region in the substrate that has a doping type similar to the doping type of the substrate. In one example, an aluminum material in the first gridline material is heated so that it reacts with the silicon containing surface of the substrate to form a p-type doped region (e.g., reference numeral 241 in FIG. 2E).

Although the invention has been described in detail with particular reference to these preferred embodiments, other embodiments can achieve the same results. Variations and modifications of the present invention will be obvious to those skilled in the art and it is intended to cover all such modifications and equivalents. The entire disclosures of all patents, references, and publications cited above are hereby incorporated by reference.

1. A solar cell device, comprising:
a substrate having a first array of vias formed between a front surface and a rear surface of the substrate;
a first gridline disposed on the rear surface; and
a second gridline disposed on the rear surface, wherein the first array of vias are disposed between the first gridline and the second gridline.

2. The solar cell device of claim 1, further comprising a doped region formed on at least a portion of the front surface, a surface of the vias in the first array of vias and at least a portion of the rear surface, wherein the doped region is doped with a first type of dopant atom and the substrate is doped with a second type of dopant atom.

3. The solar cell device of claim 2, wherein the first type of dopant atom is an n-type dopant atom and the second type of dopant atom is a p-type dopant atom.

4. The solar cell device of claim 1, further comprising a second array of vias formed between a front surface and a rear surface of the substrate, wherein the second gridline is disposed between the first array of vias and the second array of vias.

5. The solar cell device of claim 4, further comprising a doped region formed on at least a portion of the front surface, a surface of the vias in the first array of vias, a surface of the vias in the second array of vias and at least a portion of the rear surface, wherein the doped region is doped with a first type of dopant atom and the substrate is doped with a second type of dopant atom.

6. The solar cell device of claim 5, wherein the first type of dopant atom is an n-type dopant atom and the second type of dopant atom is a p-type dopant atom.

7. The solar cell device of claim 5, wherein the doped region has a sheet resistance of between about 60Ω/sq and about 80Ω/sq.

8. The solar cell device of claim 5, wherein the portion of the doped region on the front surface has a sheet resistance of between about 60Ω/sq and about 200Ω/sq, and the portion of the doped region on the rear surface has a sheet resistance of between about 20Ω/sq and about 80Ω/sq.

9. A solar cell device, comprising:
a substrate having a first array of vias and a second array of vias that are both formed between a front surface and a rear surface of the substrate, wherein the substrate is doped with a first doping element;
a doped region formed on at least a portion of the front surface, a surface of the vias in the first array of vias, a surface of the vias in the second array of vias, and at least a portion of the rear surface, wherein the doped region is doped with a second doping element that is of an opposite doping type to the first doping element;
a first gridline disposed on the rear surface and a distance along the rear surface from the first array of vias; and
a second gridline disposed on the doped region formed on the rear surface, and between the first array of vias and the second array of vias.

10. The solar cell device of claim 9, wherein the first type of dopant atom is an n-type dopant atom and the second type of dopant atom is a p-type dopant atom.

11. The solar cell device of claim 9, further comprising a dielectric material disposed on the rear surface, and between the rear surface and at least a portion of the first gridline.

12. The solar cell device of claim 11, wherein the dielectric material is disposed between the first gridline and the first array of vias.

13. The solar cell device of claim 9, wherein the doped region has a sheet resistance of between about 60Ω/sq and about 80Ω/sq.

14. The solar cell device of claim 9, wherein the portion of the doped region on the front surface has a sheet resistance of between about 60Ω/sq and about 200Ω/sq, and the portion of the doped region on the rear surface has a sheet resistance of between about 20Ω/sq and about 80Ω/sq.

15. The solar cell device of claim 9, wherein the first gridline comprises aluminum and the second gridline comprises silver.

16. A method of forming a solar cell device, comprising:
forming a first array of vias in a substrate that is doped with a first doping element, wherein the first array of vias are formed between a front surface and a rear surface of the substrate;
forming a doped region on at least a portion of the front surface, on a surface of the vias in the first array of vias and at least a portion of the rear surface, wherein the doped region is doped with a second doping element that is of an opposite doping type to the first doping element;
depositing a first gridline on the rear surface and a distance along the rear surface from the first array of vias; and
depositing a second gridline between the first array of vias and the second array of vias on the doped region formed on the at least a portion of the rear surface.

17. The method of claim 16, further comprising:
forming a second array of vias in the substrate a distance from the first array of vias in a first direction, wherein the second array of vias are formed between a front surface and a rear surface of the substrate.

18. The method of claim 17, wherein the second array of vias are staggered relative to the first array of vias in a direction different from the first direction.

19. The method of claim 16, further comprising:
depositing a dielectric material on the rear surface, wherein at least a portion of the first gridline is disposed over a portion of the dielectric material after the first gridline is deposited on the rear surface; and
heating the substrate to a desired temperature to cause a portion of the first gridline to react with a portion of the rear surface of the substrate to form a region in the substrate that has a doping type that is the same as the first doping element.

20. The method of claim 16, wherein the formed doped region has a sheet resistance of greater than about 60Ω/sq.
